(19) United States
(12) Patent Application Publication
(10) Pub. No.: US 2024/0411225 A1
(43) Pub. Date: Dec. 12, 2024

(54) SYSTEM INCLUDING HEATING MEANS AND ACTINIC RADIATION SOURCE AND A METHOD OF USING THE SAME

(71) Applicant: CANON KABUSHIKI KAISHA, Tokyo (JP)

(72) Inventors: Timothy Brian STACHOWIAK, Austin, TX (US); Fen Wan, Austin, TX (US); Weijun Liu, Cedar Park, TX (US)

(21) Appl. No.: 18/332,010

(22) Filed: Jun. 9, 2023

(51) Int. Cl. G03F 7/027; C08F 12/34; C08F 22/10; C08F 22/26; G03F 7/00

(52) U.S. Cl. CPC G03F 7/027; C08F 12/34; C08F 22/1006; C08F 22/26; G03F 7/0002

(57) ABSTRACT

A system can include a heating means for heating a photocurable composition over a substrate; an actinic radiation source configured to emit actinic radiation at a wavelength less than 700 nm; and a controller configured to determine a targeted temperature to be produced by the first heating means to achieve a photocuring temperature of the photocurable composition when the photocurable composition is exposed by the actinic radiation source, wherein the photocuring temperature is greater than an ambient temperature. A method can include dispensing the photocurable composition over a substrate; photocuring a layer of the photocurable composition at a photocuring temperature higher than ambient temperature to form a cured layer; and baking the cured layer to form a baked layer. The system and method can allow a thickness change of layer to be 0% or closer to 0%.

### FIELD OF THE DISCLOSURE

The present disclosure relates to systems including heating means and actinic radiation sources and methods of using the systems.

### RELATED ART

Ink-jet Adaptive Planarization (IAP) is used in microelectronic fabrication. As dimensions of microelectronic components continue to become smaller, processes, including IAP, become more difficult. An IAP process can include dispensing a photocurable composition over a substrate and placing a substrate in contact with the photocurable composition. The IAP process can further include photocuring a layer of the photocurable composition by exposing the photocurable composition to actinic radiation to form a cured layer. The photocuring is performed at room temperature, for example 20° C. The cured layer is then baked to form a baked layer. The thickness of the baked layer is thinner than the thickness of the photocurable composition. The thickness change reduces the planarization performance of the baked layer formed by the IAP process described above. The resulting surface of the baked layer may have a non-uniform topography that has some areas that are at a locally lower elevation and other areas that are at a locally higher elevation. A planarization layer having no elevational difference or at least less elevational differences across such surface is desired.

### SUMMARY

In an aspect, a system comprises a first heating means for heating a photocurable composition over a substrate; an actinic radiation source configured to emit actinic radiation at a wavelength less than 700 nm; and a controller configured to determine a targeted temperature to be produced by the first heating means to achieve a photocuring temperature of the photocurable composition when the photocurable composition is exposed by the actinic radiation source, wherein the photocuring temperature is greater than an ambient temperature.

In an embodiment, the system includes an apparatus, and the first heating means and the actinic radiation source are within a same station within the apparatus.

In another embodiment, the system further comprises a first substrate chuck configured to hold the substrate when the photocurable composition is at the photocuring temperature and exposed to the actinic radiation.

In a particular embodiment, the system further comprises a second substrate chuck configured to hold the substrate when the photocurable composition is exposed to the first heating means; and a substrate transfer tool configured to transfer the substrate having the photocurable composition between the first substrate chuck and the second substrate chuck.

In still another embodiment, the system further comprises a dispense head configured to dispense the photocurable composition over the substrate.

In yet another embodiment, the system further comprises a station configured to place a superstrate in contact with the photocurable composition overlying the substrate.

In a further embodiment, the system further comprises a second heating means configured to heat a cured layer corresponding to the photocurable composition to form a baked layer, wherein the second heating means is configured to heat the substrate and the cured layer to a baking temperature higher than the photocuring temperature.

In another embodiment, the system further comprises a temperature sensor configured to generate a first signal corresponding to a temperature of the photocurable composition, wherein the controller is further configured to receive the first signal and to transmit a second signal for the actinic radiation source to be activated when the temperature is at the photocuring temperature+/−5° C.

In another aspect, a method comprises dispensing a photocurable composition over a substrate, wherein the photocurable composition comprises a multifunctional monomer;

photocuring the photocurable composition while the photocurable composition is at a photocuring temperature higher than an ambient temperature, wherein photocuring the photocurable composition forms a cured layer over the substrate; and baking the cured layer to form a baked layer, wherein baking is performed at a baking temperature higher than the photocuring temperature.

In an embodiment, the photocuring temperature is greater than 25° C.

In a particular embodiment, the baking temperature is at most 500° C.

In another embodiment, the photocurable composition is at the photocuring temperature while the photocurable composition is in contact with the substrate and a superstrate.

In still another embodiment, a cured thickness is a thickness of the cured layer of the photocurable composition before baking, a baked thickness is a thickness of the baked layer, a thickness change is:
((T₂−T₁)/T₁)*100%, where
T₁ is the cured thickness,
T₂ is the baked thickness, and
the thickness change is in a range from −2.0% to 2.0%.

In a further embodiment, the multifunctional monomer comprises a difunctional monomer, a trifunctional monomer, or a tetrafunctional monomer.

In another embodiment, the multifunctional monomer includes two or more vinyl groups.

In a particular embodiment, the multifunctional monomer includes at least one aromatic ring structure.

In still another embodiment, the multifunctional monomer comprises an acrylate group.

In yet another embodiment, the photocurable composition has a multifunctional monomer content of at least 90% by weight of the photocurable composition.

In a further embodiment, the method further comprises receiving the baking temperature at which the cured layer is to be baked; and determining the photocuring temperature based on the baking temperature.

In a further aspect, a system comprises a photocure station configured to form a cured layer over a substrate at a photocuring temperature, wherein the photocuring temperature is higher than an ambient temperature; a bake station configured to bake the cured layer at a baking temperature to form a baked layer; and a controller configured to determine the photocuring temperature based at least in part on the baking temperature.

In an embodiment, the photocure station comprises a heating means configured to heat a photocurable composition over the substrate to a temperature at or closer to the photocuring temperature than the ambient temperature; and an actinic radiation source configured to emit radiation at a wavelength less than 700 nm.

In another embodiment, the system further comprises a robot arm configured to move the substrate with the cured layer from the photocure station to the bake station.

### BRIEF DESCRIPTION OF THE DRAWINGS

Implementations are illustrated by way of example and are not limited to the accompanying figures.

FIG. 1 includes an illustration of a cross-sectional view of portions of a substrate, a layer of a photocurable composition, and a superstrate before photocuring the photocurable composition.

FIG. 2 includes an illustration of a cross-sectional view of the substrate and the layer of FIG. 1 after photocuring and baking.

FIG. 3 includes a conceptual view of an apparatus that can be used in forming a layer from a photocurable composition.

FIG. 4 includes a conceptual view of another apparatus that can be used in forming a layer from a photocurable composition.

FIG. 5 includes a conceptual view of a system including apparatuses that can be used in forming a layer from a photocurable composition.

FIG. 6 includes a process flow diagram for forming a layer from a photocurable composition.

FIG. 7 includes an illustration of a cross-sectional view of a portion of a substrate chuck and a substrate when dispensing droplets of a photocurable composition over the substrate.

FIG. 8 includes an illustration of a cross-sectional view of the substrate chuck and substrate of FIG. 7 when a superstrate and a combination of the substrate and the droplets are being moved closer to each other.

FIG. 9 includes an illustration of a cross-sectional view of the substrate chuck, substrate, and superstrate of FIG. 8 when forming a layer of the photocurable composition.

FIG. 10 includes an illustration of a cross-sectional view of the substrate chuck, the substrate, the superstrate, and the layer of the photocurable composition of FIG. 9 during a pre-exposure heating operation.

FIG. 11 includes an illustration of a cross-sectional view of the substrate chuck, the substrate, the superstrate, and the layer of the photocurable composition of FIG. 10 during photocuring of the layer of the photocurable composition to form a cured layer.

FIG. 12 includes an illustration of a cross-sectional view of the substrate chuck, the substrate, the superstrate, and the cured layer of FIG. 11 after removing the superstrate and baking the cured layer to form a baked layer.

FIG. 13 includes a graph illustrating thickness change caused by a photocuring operation as a function of photocuring temperature for different sized substrate features.

FIG. 14 includes a graph illustrating thickness change caused by a baking operation as a function of photocuring temperature for different baking temperatures.

FIG. 15 includes a graph illustrating thickness change caused by a baking operation as a function of photocuring temperature for different photocurable compositions.

FIG. 16 includes a graph illustrating thickness change caused by a baking operation as a function of dose of actinic radiation for different photocuring temperatures.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

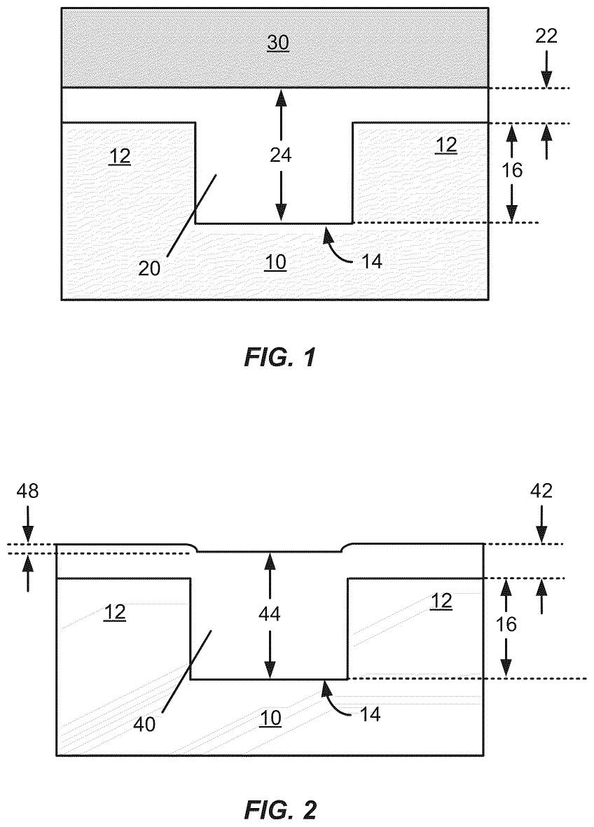

Before addressing details of systems and methods that can be used to achieve benefits as described herein, thickness changes due to processing and planarization performance is addressed and described with respect to FIGS. 1 and 2 that illustrate how the shape of a layer of a photocurable composition can change during processing. The particular thicknesses and depths are provided to illustrate a particular example and not to limit the scope of the present invention as defined in the appended claims.

FIG. 1 includes a cross-sectional view of portions of a substrate 10, a layer 20 of a photocurable composition before photocuring (hereinafter, “pre-cured layer”), and a superstrate 30 having a planar, bottom surface. The substrate 10 includes features 12 and a trench 14 between the features 12. Dimension 16 corresponds to the depth of the trench 14 and is 200 nm for this particular example.

The upper surface of the pre-cured layer 20 of the photocurable composition is planar because the photocurable composition is a fluid that contacts the planar, bottom surface of the superstrate 30. Dimension 22 corresponds to the thickness of the pre-cured layer 20 between features 12 and bottom surface of the superstrate 30. In this particular example, dimension 22 is 40 nm. Dimension 24 corresponds to the thickness of the pre-cured layer 20 between the bottom of the trench 14 and the bottom surface of the superstrate 30. Dimension 24 is a sum of dimension 16 (depth of the trench 14) and dimension 22 (thickness of the pre-cured layer over the features 12). Dimension 24 can be determined using Equation 1 below.

$${D}_{24} = {D}_{16} + {D}_{22} , \qquad ( Equation 1 )$$

where
   D₂₄ is dimension 24,
   D₁₆ is dimension 16, and
   D₂₂ is dimension 22.

When using the previously recited depth for dimension 16 and thickness for dimension 22,

D₂₄=200 nm+40 nm=240 nm.

Photocuring the pre-cured layer 20 polymerizes monomers within the photocurable composition and forms a cured layer. During polymerization, covalent bonds form between monomers within the photocurable composition and pull atoms closer together causing the photocurable composition to shrink. After photocuring, the cured layer is baked to form a baked layer 40 in FIG. 2. Additional cross-linking occurs during baking and further shrinks the polymerized material. Additionally, some rearrangement and relaxation of the polymer may occur during baking. A reaction may occur, such as oxidation, decomposition, a degradation of the material at high temperature, or a combination thereof.

The polymerization and any or all of the previously described reactions can contribute to thermal shrinkage. FIG. 2 includes the substrate 10 and the baked layer 40 after the superstrate 30 is removed. In the particular example, the baked layer 40 has shrunk by 5% (a thickness change of −5%) as compared to the pre-cured layer 20. Dimension 42 corresponds to the thickness of the baked layer 40 over the features 12, and dimension 44 corresponds to the thickness of the baked layer 20 within and over the trench 14. Due to the thickness change of −5%, dimension 42 is 95% of dimension 22, and dimension 44 is 95% of dimension 24. Thus, dimension 42 is 38 nm, and dimension 44 is 228 nm.

While the upper surface of the pre-cured layer 16 was at the same elevation, the baked layer 40 has an upper surface with different areas lying at different elevations. Dimension 48 corresponds to the elevational difference along the upper surface of the baked layer 40 between (1) portions of the baked layer 40 overlying the features 12 of the substrate 10, and (2) a portion of the baked layer 40 over the trench 14. Dimension 48 can be determined using Equation 2 below.

$${D}_{48} = {D}_{42} - ( {D}_{44} - {D}_{16} ) , \qquad ( Equation 2 )$$

where
   D₄₈ is dimension 48,
   D₄₂ is dimension 42, and
   D₄₄ is dimension 44.

When using the values for the dimensions,

D₄₈=38 nm−(228 nm-200 nm)=10 nm.

By reducing the thickness change due to photocuring and baking, dimension 48 can be reduced and help with planarization performance. When the thickness change is −1%, dimension 48 can be reduced to 1.6 nm, and when the thickness change is 0%, dimension 48 can be 0 nm.

As described herein, the amount of thickness change can be reduced by photocuring a photocurable composition at a temperature greater than the ambient temperature. Ambient temperature is the temperature of the room in which a station that performs photocuring within an apparatus is located. For example, the ambient temperature may be in a range from 20° C. to 25° C. Photocuring at the photocuring temperature can help reduce the thickness change associated with photocuring and baking can produce a baked layer having an upper surface that has less elevational differences along such upper surface as compared to a different baked layer made from the same photocurable composition, where the pre-cured layer was photocured at the ambient temperature and subsequently baked. A reduced amount of thickness change allows for better planarization performance.

In this specification, a thickness change can be between any two of (1) a pre-cured layer of a photocurable composition, (2) a cured layer corresponding to the pre-cured layer, or (3) a baked layer corresponding to the pre-cured layer. Unless explicitly stated to the contrary, the thickness change is expressed as a percentage.

A thickness change can be determined using Equation 3 below:

$$( ( {T}_{2} - {T}_{1} ) / {T}_{1} ) * 100 \% , \qquad ( Equation 3 )$$

where
   T₁ is the thickness of a layer at a relatively earlier point in the process, and
   T₂ is the thickness of the layer at a relatively later point in the process.

For example, T₁ can be the thickness of the pre-cured layer, and T₂ can be the thickness of the cured layer or the thickness of the baked layer. Alternatively, T₁ can be the thickness of the cured layer, and T₂ can be the thickness of the baked layer. A negative value corresponds to shrinkage, and a positive value corresponds to expansion. A thickness change is described in terms of how far the thickness change is from 0%. Thus, a thickness change of −4.0% may be decreased to −1.0%, although, literally, −4.0% is less than −1.0%.

Thickness measurements for determining thickness change should be at substantially the same location and surface feature, such as over a protrusion, within a recession, within a scribe lane between dies, or the like. The thickness measurements should be within an area of the substrate surrounded by an exclusion zone extending for a distance in a range from 1 mm to 9 mm from the peripheral edge toward the center of the substrate, for example 3 mm. The thickness measurements may be made using an Atomic Force Microscope (AFM); an interferometer; an ellipsometer; a profilometer; or any suitable instrument for measuring a thickness of a layer or a surface profile of a layer. As an alternative to a thickness measurement, a relative height difference at two locations may be measured as this may be representative of the planarity of the planarization layer. In an implementation, a contour map may be generated from the upper surface of a layer to illustrate elevational changes across such surface.

The thickness change can be a single thickness change or an average of a plurality of thickness changes between pairs of thickness measurements or an average from a contour map corresponding to the upper surface of a pre-cured layer, a cured layer, or a baked layer.

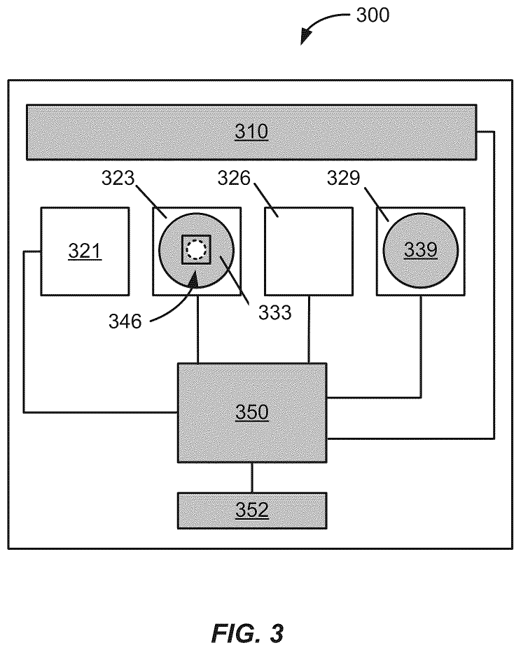

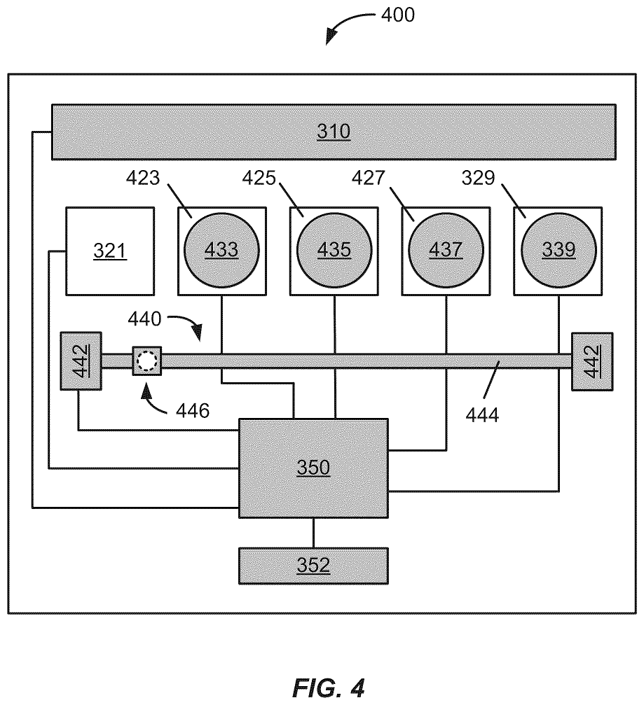

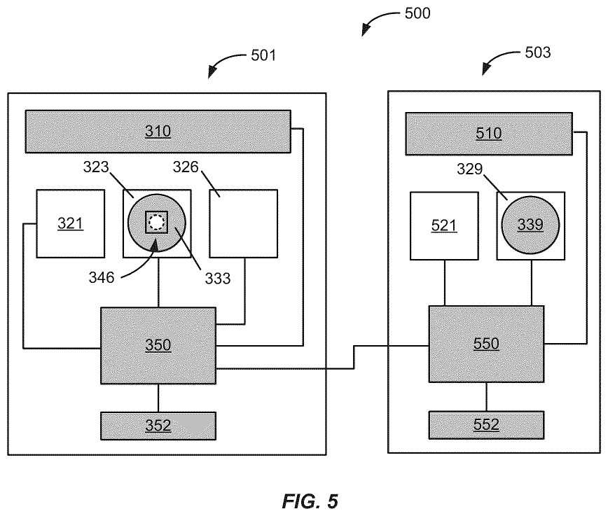

A system can be configured to perform a dispensing operation for a photocurable composition, a pre-exposure heating operation, a photocuring operation, and a baking operation. The previously listed operations for the system can be performed within a single apparatus, such as an apparatus 300 in FIG. 3 or an apparatus 400 in FIG. 4, or may distributed between two or more apparatuses, such as apparatuses 501 and 503 in FIG. 5. The systems are well suited for an IAP process. The systems can also be used in forming a patterned layer from a photocurable composition.

After reading this specification, skilled artisans will be able to determine the number of apparatuses and their corresponding operations when designing a system. In the description below, the system in FIG. 3 will be addressed before addressing the systems in FIGS. 4 and 5.

FIG. 3 includes a conceptual diagram of a top view of a system in the form of the apparatus 300 that can be used to form a layer from a photocurable composition overlying a substrate.

The apparatus 300 includes a substrate transfer tool 310, a substrate pod 321, a dispense station 323, a pre-exposure heat and photocure station 326, a post-exposure bake station 329, a controller 350, and a memory 352. The dispense station 323 can include a substrate chuck 333, the post-exposure bake station 329 can include a substrate chuck 339, and a dispense head 346. The substrate chuck 333 can be coupled to a stage (not illustrated) that allows the substrate chuck 333 to move between the stations 323 and 326. The pre-exposure heat and photocure station 326 can be configured to perform the pre-exposure heat operation and the photocuring operation. As described later with respect to FIG. 4, the pre-exposure heat operation may be performed at one station, and the photocuring operation may be performed at a different station.

Many of previously-mentioned components are described below with respect to the functions that each performs. More details regarding operation of the components, and particularly the stations 323, 326, and 329, are described in more detail later in this specification with respect to methods of using the apparatus 300.

The substrate transfer tool 310 can be configured to transfer one or more substrates to or from any of the substrate pod 321, the dispense station 323, the pre-exposure heat and photocure station 326, and the post-exposure bake station 329. The substrate transfer tool 310 may be or include one or more components of an Equipment Front End Module (EFEM). The components of the EFEM can include one or more of each of the following: a robot arm, a robot hand adapted for holding wafers, a sensor, a motor for moving the robot arm, another motor for moving the robot arm, and the like. The robot arm can be configured to move the substrate with a cured layer between stations, for example, from the pre-exposure heating and photocure station 326 to the post-exposure bake station 329. In an implementation, a particular substrate and a superstrate may have similar shapes and sizes.

The substrate pod 321 can hold a plurality of substrates. A substrate can be removed from the substrate pod 321, processed at stations of the apparatus 300, such as the stations 323, 326, 329, or a combination thereof, and returned to the substrate pod 321 when processing within the apparatus 300 is partly or completely performed.

The dispense station 323 can be configured to receive a substrate and so that a photocurable composition can be dispensed over the substrate. When the substrate is over the substrate chuck 333, the dispense head 346 can be used to dispense a photocurable composition over the substrate. The dispense head 346 can include one or more nozzles that dispense the photocurable composition. The dashed lines within the dispense head 346 are used to indicate that the photocurable composition is dispensed along the bottom side of the dispense head 346. The dispense head 346 can be configured to be stationary or move when dispensing the photocurable composition. More details regarding the photocurable composition and methods of dispensing and processing the photocurable composition are described later in this specification. A stage coupled to the substrate chuck 333 can transfer the substrate and the photocurable composition overlying the substrate from the dispense station 323 to the pre-exposure heat and photocure station 326.

The pre-exposure heat and photocure station 326 can be configured to perform two operations. The pre-exposure heat and photocure station 326 can be configured to heat the photocurable composition before exposure to actinic radiation. The pre-exposure heat and photocure station 326 can be configured to photocure the photocurable composition by exposing the photocurable composition to actinic radiation. In another implementation, the operations to be performed by the pre-exposure heat and photocure station 326 can be separated into two different stations. FIG. 4 includes a system that has the apparatus 400. The pre-exposure heat and photocure station 326 is replaced by a pre-exposure heat station 425 and a photocure station 427.

Heating means associated with the pre-exposure heat and photocure station 326 illustrated in FIG. 3 can be activated to heat the photocurable composition. More details regarding the heating means for the pre-exposure heat and photocure station 326 are described later in this specification. A direct temperature measurement of the photocurable composition may be difficult to obtain. Thus, the temperature of the photocurable composition can correspond to a different temperature within the pre-exposure heat and photocure station 326. The temperature of the photocurable composition, whether in the form of droplets or a subsequently formed pre-cured layer, may be correlated to the temperature of the substrate chuck 333, the substrate overlying the substrate chuck 333, or if present, a superstrate in contact with the photocurable composition if the superstrate is present. A temperature of the photocurable composition can be determined using the temperature of the substrate chuck 333, the substrate overlying the substrate chuck 333, or if present, a superstrate. A user of the system may control operations using the temperature of the substrate chuck 333, the substrate, or, if present, the superstrate because a direct temperature measurement of the photocurable composition may not be practical.

When the temperature of the substrate chuck 333, the substrate, or the superstrate is at a targeted temperature or within a tolerance of such temperature, the heating means can be deactivated or be put in a holding state to keep the substrate chuck 333 or the substrate at the targeted photocuring or within a tolerance of such temperature The tolerance of such temperature can be +/−5° C., 2° C., 1° C., or 0.5° C. of the targeted temperature. The targeted temperature may be the same or different from a desired photocuring temperature when photocuring the photocurable composition. The targeted temperature can be determined after a desired photocuring temperature is known. More details regarding the targeted temperature are described with respect to methods of using the apparatus 300.

The pre-exposure heat and photocure station 326 can be used to form a cured layer from the photocurable composition overlying the substrate. If a superstrate is not yet in contact with the photocurable composition, the superstrate can be placed in contact with droplets of the photocurable composition causing droplets of the photocurable composition to coalesce and form a pre-cured layer of the photocurable composition. When the pre-cured layer is at the photocuring temperature, the pre-cured layer of the photocurable composition can be photocured by exposing the pre-cured layer to actinic radiation. The actinic radiation can cause a polymerizable material within the photocurable composition to polymerize. A cured layer refers to the layer of the polymerized photocurable composition after the pre-cured layer of the photocurable composition is photocured using actinic radiation and before the layer of polymerized photocurable composition is further processed during a post-exposure baking operation. The superstrate can be removed when the photocuring operation is completed. The substrate transfer tool 310 can transfer the substrate and the cured layer from the pre-exposure heat and photocure station 326 to the post-exposure bake station 329.

The post-exposure bake station 329 can further polymerize or crosslink the photocurable composition within the cured layer, cause a different reaction of a component within the photocurable composition, drive out a volatile component within the photocurable composition, or the like. The post-exposure bake station 329 can have any of the designs, including the heating means, as described with respect to the pre-exposure heat and photocure station 326. The heating means for the post-exposure bake station 329 can be the same or different from the heat means for the pre-exposure heat and photocure station 326. In an implementation, the post-exposure bake station 329 can include a heating means configured to operate at a higher temperature as compared to the pre-exposure heat and photocure station 326. The temperature used for post-exposure baking may be at least 150° C. The highest processing temperature associated with the post-exposure bake station 329 may be as high as 500° C. Sufficient thermal shielding may be used to help keep heat from the post-exposure bake station 329 from adversely affecting operation of another portion of the apparatus 300.

Each of the substrate chucks 333 and 339 can be a vacuum chuck, a pin-type chuck, a groove-type chuck, an electrostatic chuck, an electromagnetic chuck, or the like. The substrate chucks 333 and 339 may be the same type, for example, vacuum chucks, or may be different types. For example, one of the substrate chucks can be a vacuum chuck, and another one of the substrate chucks can be an electrostatic or electromagnetic chuck. Each of the substrate chucks 333 and 339 may or may not have a heating element, a cooling element, or both that can be used to heat or cool a substrate and a layer, and if present, a superstrate overlying the substrate.

A stage can be coupled to one or more of the substrate chucks and be used to move the substrate chuck within the apparatus 300. Different stages can be coupled to different substrate chucks or a combination of such substrate chucks can be coupled to the same stage. A stage may also allow fewer substrate chucks to be used. A substrate chuck may be coupled to a stage that can be moved between at least two of the different stations. Thus, each station is not required to have a dedicated substrate chuck. In a non-limiting example, a substrate can be placed on the substrate chuck 333 coupled to a stage that is positioned within the dispense station 323, and after the photocurable composition is dispensed, the stage can move the substrate chuck 333, the substrate, and the photocurable composition to the pre-exposure heat and photocure station 326. After operations in the pre-exposure heat and photocure station 326 are completed and the substrate and cured layer is removed, the stage can move the substrate chuck 333 back to the dispense station 323 in order to receive another subsequent substrate. In another implementation described later with respect to FIG. 4, each station may have a dedicated substrate chuck.

The controller 350 can control the apparatus 300 in FIG. 3, the apparatus 400 in FIG. 4, or the apparatus 501 in FIG. 5. The description of the controller 350 below is focused on apparatus 300 in FIG. 3. The description of the controller 350 also applies to the apparatus 400 in FIG. 4 and the apparatus 501 in FIG. 5 except as noted when addressing specific details of the apparatuses 400 and 501.

The controller 350 can be in communication with any or all of the components of the apparatus 300 that have been previously described and potentially other components within the apparatus 300 or external to the apparatus 300. The controller 350 can operate using a computer readable program, optionally stored in memory 352. The controller 350 can include a processor (for example, a central processing unit of a microprocessor or microcontroller), a field-programmable gate array (FPGA), an application specific integrated circuit (ASIC), or the like. The controller 350 can be within the apparatus 300. In another implementation (not illustrated) of the system, the controller 350 can be at least part of a computer external to the apparatus 300, where such computer is bidirectionally coupled to the apparatus 300. The memory 352 can include a non-transitory computer readable medium that includes instructions to carry out the actions associated with or between transfer operations. The memory 352 can further include data tables that can be accessed by the controller 350 to assist in determining an operating parameter, for example, a local areal density of the photocuring composition to be dispensed, a targeted temperature, a photocuring temperature, a dose of actinic radiation, a post-exposure baking temperature, or another parameter used in the methods as described below. Similar to the controller 350, the memory 352 can be part of the system and may be within the apparatus 300 or external to the apparatus 300. In another implementation, any or all of the components can include a local controller that provides some of the functionality that would otherwise be provided by the controller 350.

The previously described operation performed by any particular station may be moved or combined with another station. For example, the dispensing and pre-exposure heating and photocuring can be performed within the same station, the pre-exposure heating and photocuring can be performed within the same station, etc. In another configuration, operations performed by one station may be performed in separate stations. FIG. 4 includes a conceptual diagram of a top view of another system in the form of an apparatus 400 that can be used to form a baked layer over a substrate. The apparatus 400 is the same as the apparatus 300 except as described below.

The pre-exposure heat and photocure station 326 in FIG. 3 is replaced by a pre-exposure heat station 425 and a photocure station 427 in FIG. 4. The designs for each of the stations 425 and 427 may be optimized more readily as compared to the pre-exposure heat and photocure station 326 that performs both the pre-exposure heating and photocuring operations. The separate stations 425 and 427 may add to the cost of the apparatus 400 as compared to the apparatus 300 due to more components, and the footprint of the apparatus 400 may be larger than the footprint of the apparatus 300.

The dispense head 346 in FIG. 3 is replaced by a dispense module 440 in FIG. 4. The dispense module 440 is configured to dispense the photocurable composition over a substrate when the substrate is at a dispense station 423. The dispense station 423 provides the functions as previously described with respect to the dispense station 323. The dispense module 440 can be a gantry-based system that includes ends 442 that are coupled to rails (not illustrated) and allow the dispense module 440 to move in a direction corresponding to the top and bottom of FIG. 4. The dispense module 440 includes a bridge 444 that is coupled to the ends 442 and can pass over the substrate chuck 433. A dispense head 446 is coupled to and configured to move along the bridge 444 between the left-hand side and the right-hand side of FIG. 4. The dispense head 446 can include one or more nozzles that dispense the photocurable composition. The dashed lines within the dispense head 446 are used to indicate that the photocurable composition is dispensed along the bottom side of the dispense head 446. The dispense module 440 is configured to dispense the photocurable composition at different areal densities as described below with respect to the dispense head 346.

A substrate chucks 433, 435, and 437 have any of the configurations as previously described with respect to the substrate chucks 333 and 339. In FIG. 4, each station has a dedicated substrate chuck. Any one of the substrate chucks 433, 435, and 437 may be coupled to a stage that can help move the substrate chuck. The substrate chuck 433 may move to help during the dispensing of the photocurable composition. As compared to the substrate chuck 433, the substrate chucks 435 and 437 may not need to move and do not need to be coupled to a stage. In another implementation, any one or more of the substrate chucks in FIG. 4 can be replaced with a substrate chuck similar to the substrate chuck 333 that is coupled to a stage to allow for movement between any two or more of the stations 423, 435, and 427 illustrated in FIG. 4.

The controller 350 is coupled to the stations 423, 425, and 427 in FIG. 4 and their components and supports the dispense, pre-exposure heating, and photocuring operations as previously described with respect to FIG. 3.

Not all of the stations in the apparatus 300 or the apparatus 400 may be present within a single apparatus. Any one or more of the stations 323, 326, 329, 423, 425, and 427 may be located in different apparatuses. As a non-limiting example, the temperature at which the post-exposure bake station 329 operates may be too high for one or more other stations in the apparatus. The post-exposure bake station 329 may interfere with proper temperature control of the pre-cured layer of photocurable composition during photocuring within the station 326 in FIG. 3 or the station 427 in FIG. 4.

FIG. 5 includes a system 500 that includes the apparatuses 501 and 503. The apparatus 501 is the same as the apparatus 300 in FIG. 3 except that the post-exposure bake station 329 and the substrate chuck 339 are moved to the apparatus 503. The apparatus 503 can further include a substrate transfer tool 510, a substrate pod 521, a controller 550, and a memory 552. The substrate transfer tool 510 provides the same functionality described with respect to the substrate transfer tool 310, and the substrate pod 521 provides the same functionality described with respect to the substrate pod 321.

The controller 550 and the memory 552 can be used to provide functionality to support the substrate transfer tool 510, the substrate pod 521, the post-exposure bake station 329, and the substrate chuck 339. The controller 550 can have any of the architectures and components as described with respect to the controller 350, and the memory 552 can have any of the architectures and components as described with respect to the memory 352.

The controllers 350 and 550 can communicate with each other. For example, one or both controllers 350 and 550 can be used to confirm that a particular lot of substrates with cured layers at the substrate pod 521 have completed processing within the apparatus 501 before the substrates and cured layers are baked at the post-exposure bake station 329 in the apparatus 503. In another embodiment, the apparatuses 501 and 503 can share a common controller, a common memory, or both a common controller and a common memory, rather than having separate controllers or separate memories in the apparatuses 501 and 503.

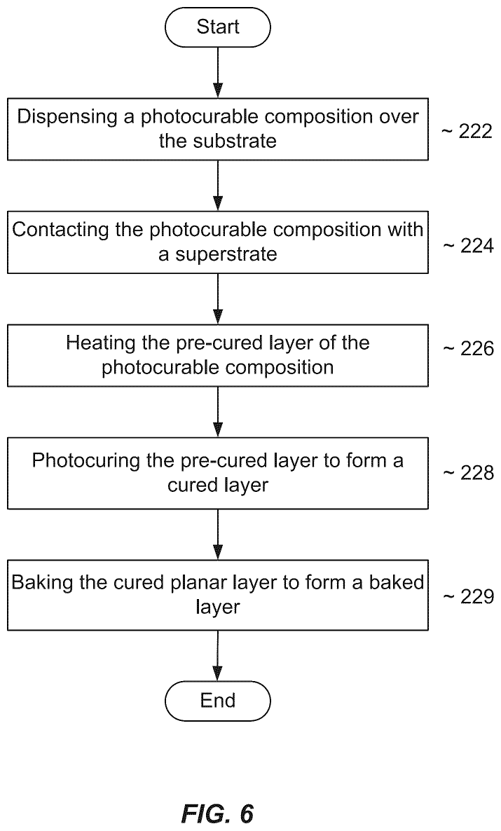

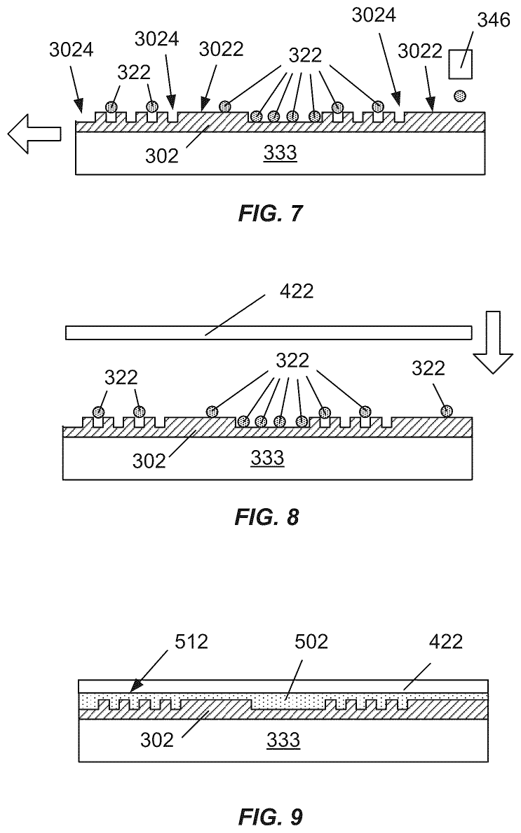

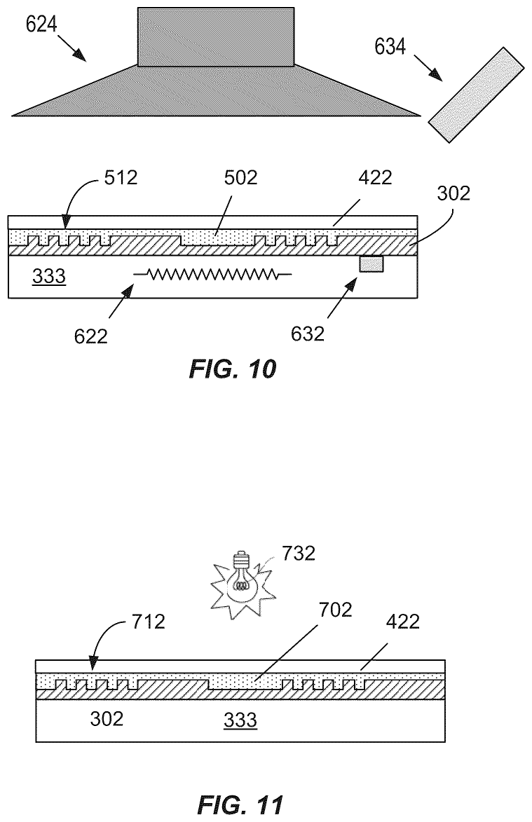

Attention is directed to methods of using the apparatus 300 to form a baked layer over a substrate. FIG. 6 includes a process flow diagram of a method that is described with respect to FIGS. 3 and 7 to 12. A particular process flow is described below in conjunction with the figures and is directed to an IAP process. Many different process flows can be used and still achieve the benefits using the concepts described herein. For example, the process may be used in imprint lithography where a patterned resist layer is a photocurable composition made using a patterned superstrate. As used hereinafter, an unpatterned superstrate is referred to as a blank, and a patterned superstrate is referred to as a template. Other variants from the process flow are described later in this specification. After describing the method with respect to the apparatus 300, other alternatives, such as how the processing may be changed when using the apparatus 400 in FIG. 4 or the system 500 in FIG. 5, are described. The substrate chuck 333 in FIGS. 7 to 9, 11, 12 can include a heating means, a temperature sensor, or both, such as illustrated in FIG. 10. The heating means and temperature sensor within the substrate chuck 333 in FIG. 10 are not illustrated in FIGS. 7 to 9, 11, and 12 to simplify understanding of operations performed in conjunction with FIGS. 7 to 9, 11, and 12.

Referring to FIG. 3, the method can include transferring a substrate from the substrate pod 321 to the dispense station 323. The controller 350 or a local controller can transmit a signal for the substrate transfer tool 310 to remove the substrate from the substrate pod 321 and move the substrate to the dispense station 323. The substrate transfer tool 310 can place the substrate on the substrate chuck 333 within the dispense station 323.

The method can include dispensing a photocurable composition over the substrate at block 222 in FIG. 6. The photocurable composition can include a polymerizable material and a photoinitiator. The photocurable composition may or may not include a solvent. In a further implementation, the photocurable composition can contain another additive. A non-limiting example of the other additive can be a surfactant, a dispersant, a stabilizer, an inhibitor, a dye, or a combination thereof.

The polymerizable material can include a single monomer compound or a mixture of monomer compounds. In an embodiment, the polymerizable material can include a multifunctional monomer. The multifunctional monomer in the photocurable composition can make up a majority of the photocurable composition on a weight percent basis. In one embodiment, the amount of the multifunctional monomer in the photocurable composition can be at least 60 wt % based on the total weight of the photocurable composition, or at least 70 wt %, or at least 80 wt %, or at least 90 wt %, or at least 92 wt %, or at least 95 wt % based on the total weight of the photocurable composition. In another implementation, the amount of multifunctional monomer may be at most 99.5 wt % based on the total weight of the photocurable composition, such as at most 99 wt %, or at most 98 wt %, or at most 97 wt %, or at most 95 wt %, or at most 93 wt %, or at most 90 wt % based on the total weight of the photocurable composition. Moreover, the amount of multifunctional monomer can be within a range containing any of the minimum and maximum values noted above, for example, in a range from 60 wt % to 99.5 wt %, 70 wt % to 99 wt %, 80 wt % to 98 wt %, or 90 wt % to 97 wt % based on the total weight of the photocurable composition.

In one implementation, the multifunctional monomer can be a difunctional monomer, a trifunctional monomer, or a tetrafunctional monomer. A functional group can be a vinyl group, an acrylate group, an acrylamide group, a methacrylate group, a maleimide group, an epoxy group, a lactone group, an acetal group, a cyclic ether group, a lactam group, a hydroxyl group, a carboxyl group, a sulfide group, or an amine group, amongst other possibilities. The multifunctional monomer compound can include the same type of functional group (for example, all functional groups within the multifunctional monomer compound are vinyl groups) or different types of functional groups. In an implementation, the multifunctional monomer can include a multifunctional acrylate monomer, a multifunctional vinyl monomer, or a combination thereof.

In a particular implementation, the multifunctional monomer can include at least two acrylate groups or at least three or at least four acrylate groups. As used herein, the term acrylate monomer relates to substituted and non-substituted acrylate monomers. Non-limiting examples of substituted acrylate monomers can be C₁-C₈ alkylacrylate, for example, methacrylate or ethylacrylate.

In another implementation, the multifunctional monomer can include at least two or at least three or at least four vinyl groups.

In an implementation, the multifunctional monomer can include both an acrylate group and a vinyl group. In another implementation, the multifunctional monomer can further include one or more aromatic ring structures.

Another multifunctional monomer can include two or more vinyl groups, and at least one aromatic ring structure, for example, one or more benzene rings. In an implementation, the multifunctional monomer can include a vinyl benzene or divinylbenzene compound. In a particular implementation, the multifunctional monomer can be a biphenyl or diphenylmethane compound including two, three, or four vinyl groups.

Table 1 below includes a list of exemplary multifunctional monomer compounds that can be used as the polymerizable material in the photocurable composition. The list is intended to be illustrative, not comprehensive, and not intended to limit polymerizable material compounds that can be used.

TABLE 1
Exemplary Multifunctional Monomer Compounds

| Abbreviation/Tradename | Chemical Name | CAS | Structure |
|---|---|---|---|
| TMPTA | Trimethylolpropane triacrylate | 15625-89-5 | 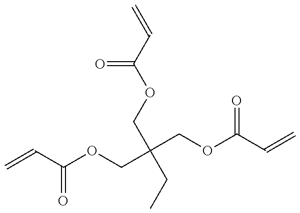 [SMILES: C=CC(=O)OCC(CC)(COC(=O)C=C)COC(=O)C=C] |
| mXDA | 1,3-Phenylenebis(methylene) bisacrylate OR m-xylylene diacrylate | 22757-16-0 | 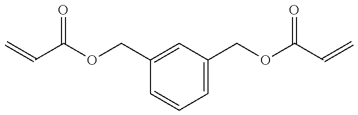 [SMILES: C=CC(=O)OCc1cccc(COC(=O)C=C)c1] |
| VmXDA | 3,5-Bis(methylene) diacrylate styrene | NA | 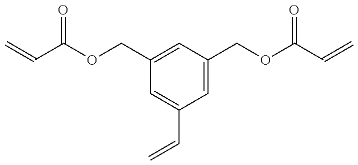 [SMILES: C=CC(=O)OCc1cc(C=C)cc(COC(=O)C=C)c1] |
| DVBA | 3,5-Divinyl benzyl acrylate | NA | 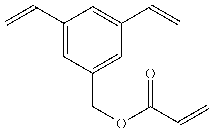 [SMILES: C=CC(=O)OCc1cc(C=C)cc(C=C)c1] |
| DVBPH | 3,3′-Divinyl-1,1′-biphenyl | NA | 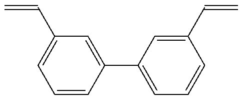 [SMILES: C=Cc1cccc(-c2cccc(C=C)c2)c1] |
| 3VBPH | 3,4′,5-Trivinyl-1,1′-biphenyl | NA | 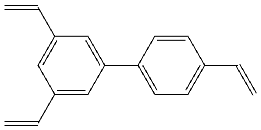 [SMILES: C=Cc1ccc(-c2cc(C=C)cc(C=C)c2)cc1] |
| TVPM | 3,5,3′- Trivinyldiphenylmethane | NA | 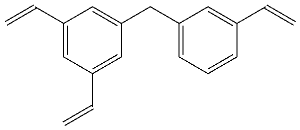 [SMILES: C=Cc1cccc(Cc2cc(C=C)cc(C=C)c2)c1] |
| BVPM | 3,3′-Trivinyldiphenylmethane | NA | 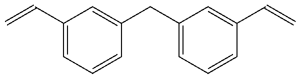 [SMILES: C=Cc1cccc(Cc2cccc(C=C)c2)c1] |
| 4VPM | 3,5,3′,5′- Tetravinyldiphenylmethane | NA | 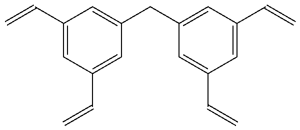 [SMILES: C=Cc1cc(C=C)cc(Cc2cc(C=C)cc(C=C)c2)c1] |
| BPADA | bisphenol A diacrylate | 4491-03-06 | 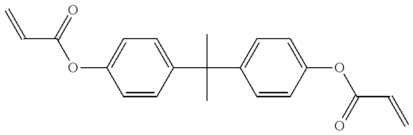 [SMILES: C=CC(=O)Oc1ccc(C(C)(C)c2ccc(OC(=O)C=C)cc2)cc1] |
| BPADMA | bisphenol A dimethacrylate | 3253-39-2 | 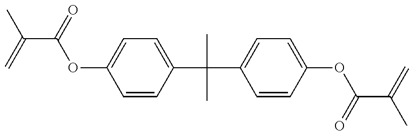 [SMILES: C=C(C)C(=O)Oc1ccc(C(C)(C)c2ccc(OC(=O)C(=C)C)cc2)cc1] |
| DCPDA | Tricyclo[5.2.1.02,6] decanedimethanol diacrylate | 42594-17-2 | 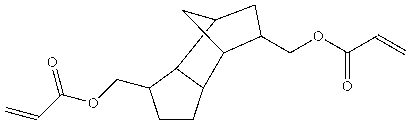 [SMILES: C=CC(=O)OCC1CC2CC1C1CCC(COC(=O)C=C)C21] |
| DVB | 1,3-divinylbenzene | 108-57-6 | 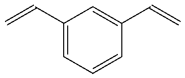 |
| TMTA | tetramethylolmethane tetraacrylate | 4986-89-4 | 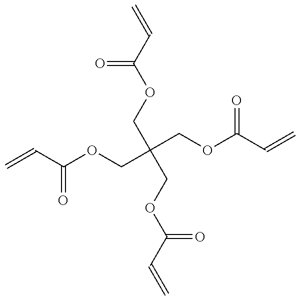 [SMILES: C=CC(=O)OCC(COC(=O)C=C)(COC(=O)C=C)COC(=O)C=C] |

The photoinitiator can include a single photoinitiator compound or a mixture of photoinitiator compounds. In the same or another implementation, a photoinitiator compound can be an oxime ester compound. The oxime ester compound can have a structure of formula (1):

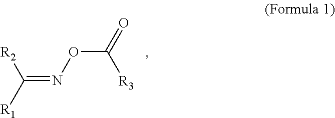

where
   R₁ being an aromatic ring system or a heteroaromatic ring system,
   R₂ being H or C₁-C₈ alkyl, and
   R₃ being H or C₁-C₈ alkyl.

In a particular implementation, the photoinitiator of the photocurable composition can further include a photoinitiator compound that is not an oxime ester compound.

Table 2 below includes a list of exemplary photoinitiator compounds that can be used in the photocurable composition. The list is intended to be illustrative, not comprehensive, and not intended to limit photoinitiator compounds that can be used.

TABLE 2
Exemplary Photoinitiator Compounds

| Abbreviation/ | | | |
|---|---|---|---|
| Tradename | Chemical Name | CAS | Structure |
| Irgacure 819 | Phenylbis(2,4,6- trimethylbenzoyl)phosphine oxide | 162881- 26-7 | 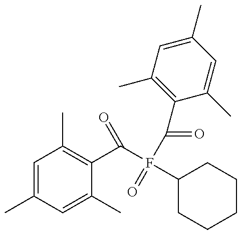 |
| Irgacure OXE-02 | 1-[({1-[9-Ethyl-6-(2- methylbenzoyl)-9H-carbazol- 3-yl]ethylidene }amino)oxy]ethenone | 478556- 66-0 | 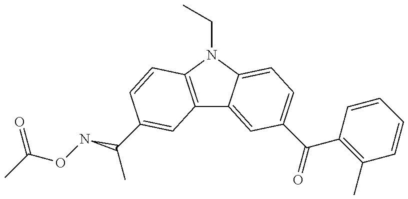 |
| Irgacure OXE-03 | | | 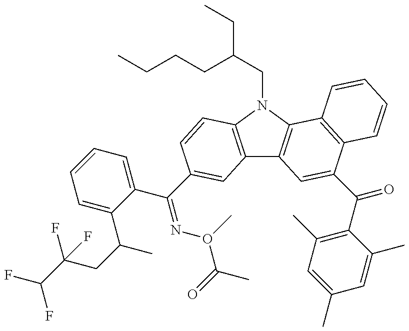 |
| Irgacure OXE-01 | 1-[4-(Phenylthio)phenyl]- 1,2-octanedione 2-(O- benzoyloxime) | 253585- 83-0 | 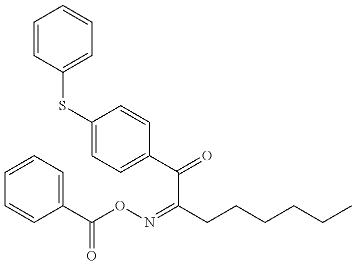 [SMILES: CCCCCC/C(=N/OC(=O)c1ccccc1)C(=O)c1ccc(Sc2ccccc2)cc1] |
| Irgacure 651 | 2,2-Dimethoxy-2- phenylacetophenone | 24650- 42-8 | 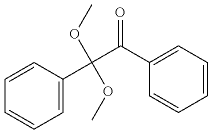 [SMILES: COC(OC)(C(=O)c1ccccc1)c1ccccc1] |
| Omnirad 1316 | | NA | 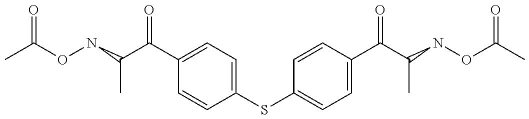 |

Irgacure compounds are available from BASF SE of Ludwigshafen am Rhein, Germany. Omnirad is available from IGM Group of Waalwijk Netherlands.

The amount of the photoinitiator in the photocurable composition can be at least 1.0 wt % based on the total weight of the photocurable composition, at least 1.5 wt %, at least 2.0 wt %, at least 2.5 wt %, at least 3.0 wt %, at least 3.5 wt %, or at least 4.0 wt % based on the total weight of the photocurable composition. In another aspect, the amount of the photoinitiator in the photocurable composition may be at most 10.0 wt % based on the total weight of the photocurable composition, at most 8.0 wt %, at most 7.0 wt %, at most 6.0 wt %, at most 5.0 wt %, or at most 4.0 wt % based on the total weight of the photocurable composition. The amount of the photoinitiator in the photocurable composition can be a value between any of the minimum and maximum numbers noted above, for example, in a range from 1.0 wt % to 10.0 wt %, 1.5 wt % to 8.0 wt %, or 2.0 wt % to 7.0 wt % based on the total weight of the photocurable composition.

In an implementation, the photocurable composition can be essentially free of a solvent. As used herein, if not indicated otherwise, the term solvent relates to a compound which can dissolve or disperse the polymerizable material but does not itself polymerize during photocuring of the photocurable composition. The term “essentially free of a solvent” means herein an amount of solvent being at most 5 wt % based on the total weight of the photocurable composition. In a particular implementation, the amount of a solvent can be at most 3 wt %, at most 2 wt %, at most 1 wt % based on the total weight of the photocurable composition, or the photocurable composition can be free of a solvent, except for unavoidable impurities.

In another aspect, the photocurable composition can comprise a solvent in an amount greater than 5 wt % based on the total weight of the photocurable composition. In a particular aspect, the amount of solvent can be at least 10 wt % based on the total weight of the photocurable composition, or at least 15 wt %, at least 20 wt %, or at least 25 wt % based on the total weight of the photocurable composition. In another aspect, the amount of solvent may be at most 40 wt %, at most 30 wt %, at most 20 wt %, or at most 10 wt % based on the total weight of the photocurable composition. In a particular implementation, the amount of the solvent in the photocurable composition can be a value between any of the minimum and maximum numbers noted above, for example, in a range from 5 wt % to 40 wt %, 10 wt % to 30 wt %, or 15 wt % to 20 wt % based on the total weight of the photocurable composition.

The surfactant can include a single surfactant compound or a mixture of surfactants. A surfactant compound can be a fluorine-containing compound, and in an implementation, the surfactant compound can be a fluoro-organic compound. Table 3 below includes a list of exemplary surfactant compounds that can be used in the photocurable composition. The list is intended to be illustrative, is not comprehensive, and not intended to limit surfactant compounds that can be used.

TABLE 3
Exemplary Surfactant Compounds

| Abbreviation/ | | | |
|---|---|---|---|
| Tradename | Chemical Type | CAS | Structure |
| FS2000M1 | Nonionic fluorosurfactant | 1702364-63-3 | NA |
| | (poly(oxyalkylene) based | | |
| | fluorosurfactant) | | |
| Capstone FS- | nonionic fluorosurfactant | NA | NA |
| 3100 | | | |

Capstone™ FS-3100 is available from The Chemours Company of Wilmington, DE, USA.

The surfactant can be at most 5.0 wt % based on the total weight of the photocurable composition. In a particular implementation, the amount of a surfactant can be at most 3.0 wt %, at most 2.0 wt %, or at most 0.9 wt % based on the total weight of the photocurable composition.

Returning to the method and FIGS. 3 and 7, the dispense head 346 dispenses droplets 322 of the photocurable composition over the exposed surface of the substrate 302 as illustrated in FIG. 7. During a dispensing operation, the substrate chuck 333 can be coupled to a stage that is configured to move the substrate chuck 333 (illustrated by the arrow adjacent to the substrate 302 in FIG. 7) during a dispensing operation. In another implementation, the dispense head 346 moves while the substrate chuck 333 is stationary. Thus, the substrate 302 can move, and the dispense head 346 may be stationary or also move.

The substrate 302 can have an exposed surface having a projection that lies at a relative higher elevation as compared to an adjacent recession. In FIG. 7, the exposed surface of the substrate 302 has protrusions 3022 and recessions 3024. The substrate 302 has a local area with a relatively higher areal density of protrusions 3022 as compared to the recessions 3024 and another local area with a relatively higher areal density of recessions 3024 as compared to the protrusions 3022. A lower areal density of the photocurable composition is dispensed where protrusions 3022 occupy a relatively larger fraction of a local area, and a higher areal density of the photocurable composition is dispensed where recessions 3024 occupy a relatively larger fraction of a different local area. In practice, the exposed surface of the substrate 302 is significantly more complex than illustrated in FIG. 7 and is not limited to only two elevations. The exposed surface of the substrate 302 in FIG. 7 is simplified to aid in understanding the concepts described herein.

The controller 350 or a local controller can transmit signals so that the dispense head 346, a stage coupled to the substrate chuck 333 (when the substrate chuck 333 is coupled to the stage), or both move in a desired direction and velocity, and the dispense head 346 dispenses the droplets 322 of the photocurable composition at a desired rate in order to achieve proper local areal densities of the photocurable composition along the exposed surface of the substrate 302.

Referring to FIGS. 3, 7, and 8, a stage coupled to the substrate chuck 333 can transfer the substrate 302 and the droplets 322 of the photocurable composition from the dispense station 323 to the pre-exposure heat and photocure station 326. The controller 350 or a local controller can transmit a signal for the stage to move the substrate chuck 333, the substrate 302 and the droplets 322 of the photocurable composition from the dispense station 323 to the pre-exposure heat and photocure station 326.

The process further includes contacting the photocurable composition with a superstrate at block 224 in FIG. 6. A superstrate 422 can be used to aid in forming a cured layer from the droplets 322 of the photocurable composition. In an implementation, the superstrate 422 can be a blank with a planar bottom surface facing the substrate 302 and the droplets 322. Each of the apparatuses 300, 400, and 501 can include a superstrate handler that can be used to move and position the superstrate 422. In the same or different implementation, the superstrate 422 can be held by a planarization head within the pre-exposure heat and photocure station 326.

The superstrate 422 has a transmittance of at least 70%, at least 80%, at least 85%, or at least 90% for actinic radiation used to photocure the photocurable composition. The superstrate 422 can include a glass-based material, silicon, an organic polymer, a siloxane polymer, a fluorocarbon polymer, a sapphire, a spinel, another similar material, or any combination thereof. The glass-based material can include soda lime glass, borosilicate glass, alkali-barium silicate glass, aluminosilicate glass, quartz, fused-silica, or the like. In an implementation, the actinic radiation can be ultraviolet radiation, and a glass-based material can be used for the superstrate 422. The superstrate 422 can have a thickness in a range from 30 microns to 2000 microns. The contacting surface of the superstrate 422 can have a surface area that is at least 90% of the area of the substrate 302 and may have surface area that is the same or larger than the substrate 302.

The contacting surface of the superstrate 422 has a two-dimensional shape including a circle, an ellipse, a rectangle (including a square), a hexagon, or the like. In the implementation illustrated in FIG. 8, the contacting surface does not have any recessions and protrusions and can be referred to as a blank. In an alternative implementation, the superstrate has recessions and protrusions which are then transferred into the photocurable composition.

Referring to FIGS. 3, 8, and 9, the controller 350 or a local controller can transmit a signal for the superstrate 422 and the droplets 322 to move closer and contact each other. The superstrate 422 may be moved, the substrate chuck 333 may be moved, or both the superstrate 422 and the substrate chuck 333 can be moved. As the superstrate 422 contacts droplets 322 of the photocurable composition, and the droplets 322 can coalesce to form a pre-cured layer 502 of the photocurable composition. The upper surface 512 of the pre-cured layer 502 conforms to the bottom, contacting surface of the superstrate 422.

The process further includes heating the pre-cured layer of the photocurable composition at block 226 in FIG. 6. Block 226 may be performed while the photocurable composition is between the substrate 302 and the superstrate 422 and/or may start prior to or during block 224. During photocuring or a subsequent baking operation, the pre-cured layer 502 or a cured layer formed from the pre-cured layer 502 can have a thickness change after photocuring, after the subsequent baking operation, or both. A targeted temperature for the pre-exposure heating may depend on the desired photocuring temperature when the pre-cured layer 502 is exposed to actinic radiation. The desired photocuring temperature may depend on the thickness change between the pre-cured layer 502 and its corresponding baked layer after photocuring and baking or between a cured layer and its corresponding baked layer.

The elevated photocuring temperature may allow a thickness change of 0% or closer to 0% between the pre-cured layer 502 and its corresponding baked layer or between the cured layer and its corresponding baked layer. The desired photocuring temperature can depend on materials within the photocurable composition. Of the materials within the photocurable composition, the polymerizable material has the largest impact on the temperature selected. The photoinitiator, which can include a single photoinitiator compound or a mixture of photoinitiator compounds, can have a smaller impact on the temperature selected. Other materials within the photocurable composition may have no impact or an insignificant impact on the temperature selected for the pre-exposure heating.

Empirical data can be generated to determine a desired photocuring temperature. After photocuring and baking, the thickness of the baked layer may be thicker, thinner, or approximately the same as the thickness of the pre-cured layer 502 or the cured layer. Graphs may be generated from the empirical data to determine the thickness change. Significant variables for the graphs can include (1) the particular photocurable composition, (2) the post-exposure baking temperature, (3) the photocuring temperature, and (4) the dose of actinic radiation during photocuring. Data for thickness changes and the four variables may be stored in a table within the memory 352. For each line within a graph, three of the four variables can be held constant while the last of the three or four variables is varied to determine its impact on the thickness change. For example, for a particular photocurable composition, baking temperature, and dose are held constant as the photocuring temperature is varied. More details regarding the empirical data can be found in the Examples section later in this specification.

The thickness change between the pre-cured layer 502 and its corresponding baked layer can be within a tolerance range of a targeted thickness change. A targeted thickness change can be 0%, and the tolerance range may be within a range of values that provide good planarization performance. The tolerance range can be +/−2.0%, +/−1.0%, or +/−0.5%. For example, a production specification may have a thickness change that is 0%+/−1.0%, and thus, the thickness range can be in a range from −1.0% to 1.0%. For a particular combination of a particular photocurable composition and a particular baking temperature, a thickness change of 0% may not be achievable. For example, such combination may only achieve a thickness change of −1% at best. The desired photocuring temperature corresponding to a thickness change at or near −1% may be selected.

The empirical data can be stored within a table in the memory 352 or a database external to the apparatus 300. The controller 350 can receive information regarding the photocurable composition, the dose of actinic radiation, the baking temperature, or a combination thereof that will be used in forming the baked layer and determine a desired photocuring temperature that is to be used.

After the desired photocuring temperature is determined, a targeted temperature during the pre-exposure heating can be determined by the controller 350 or a local controller. The targeted temperature can be the same as or different from the desired photocuring temperature. For example, the substrate 302, the pre-cured layer 502, and the superstrate 422 may or may not cool between pre-exposure heating and photocuring the pre-cured layer 502. Pre-exposure heating and photocuring the pre-cured layer can be performed in the pre-exposure heat and photocure station 326, and the targeted temperature and the desired photocuring temperature may be the same. Referring briefly to FIG. 4, the pre-cured layer 502 may cool as the substrate 302, the pre-cured layer 502, and the superstrate 422 are moved from the pre-exposure heat station 425 to the photocure station 427. The targeted temperature may be higher than the desired photocuring temperature, so that the pre-cured layer 502 cools to the desired photocuring temperature when it is in the photocure station 427. After reading this specification, skilled artisans will be able to determine a targeted temperature for a particular equipment set and a potential temperature change between pre-exposure heating and photocuring the pre-cured layer 502.

A heating means is used to heat the substrate 302, the pre-cured layer 502, and the superstrate 422 to the targeted temperature. Referring to FIG. 10, the heating means can include a resistive heating element 622 within the substrate chuck 333 or a radiative heating element 624 positioned over the substrate chuck 333. The radiative heating element 624 can include a heat lamp, an infrared lamp, or the like. Although not illustrated, the heating means can include an electromagnet to assist in heating using induction, a microwave generator to generate microwaves, a pump to assist in flowing a heated fluid through a channel within the substrate chuck 333 or a fan to assist in convection by passing a heated gas over the substrate 302, and pre-cured layer 502, and the superstate 422. The heating means may have only one type of the heating means (for example, resistive heating element, electromagnet for inductive heating, radiative heating element, microwave generator, a pump to flow a heated fluid within the substrate chuck 333, or a fan to assist in convective heating) or a combination of different types of heating means (combination of any two or more of foregoing).

The heating means provides heat so that the substrate 302, the pre-cured layer 502, and the superstrate 422 reach the targeted temperature that is higher than the ambient temperature. A room in which the apparatus 300 is located can be at an ambient temperature of 20° C. In such a room, heating can raise the temperature of the pre-cured layer 502 so that the pre-cured layer 502 is at 21° C. or higher when exposed to actinic radiation. The room may reach an ambient temperature of 24° C. while the apparatus 300 is operating, and heating can raise the temperature of the pre-cured layer 502 so that the pre-cured layer 502 is at 25° C. or higher when exposed to actinic radiation. Depending on the ambient temperature, the targeted temperature can be at least 21° C., at least 25° C., at least 30° C., at least 35° C., or at least 40° C.

When the photocurable composition within the pre-cured layer 502 is exposed to a sufficiently high temperature, the photocurable composition can substantially polymerize without being exposed to actinic radiation. Thus, the targeted temperature should not be so high as to cause substantial polymerization of the photocurable composition during the pre-exposure heating. In an implementation, the targeted temperature may be at most 150° C. In which case, an insignificant amount of polymerization may occur at 150° C. In another implementation, the targeted temperature of the pre-exposure heating can be at most 100° C., at most 80° C., or at most 70° C. The targeted temperature of the pre-exposure heating can be a value between any of the minimum and maximum numbers noted above, for example, in a range from 21° C. to 150° C. 25° C. to 100° C., 30° C. to 80° C., or 35° C. to 70° C.

During pre-exposure heating, the controller 350 or a local controller can receive temperature data from a temperature sensor 632 or 634 and transmit a signal so that the heating means, such as the resistive heating element 622 or the radiative heat element 624, heats the substrate 302, the pre-cured layer 502, and the superstrate 422 to the targeted temperature.

The method can include photocuring the photocurable composition to form a cured layer at block 228 in FIG. 6. Referring to FIG. 3, for a particular photocurable composition, the memory 352 can include information regarding a targeted wavelength or a targeted range of wavelengths for the actinic radiation, a targeted dose or a targeted range of doses to be used for the photocurable composition, or other data related to photocuring the photocurable composition. Such information can be used by the controller 350 or a local controller to determine parameters for exposing the photocurable composition to the actinic radiation. The controller 350 can access the previously described empirical data that can provide the desired photocuring temperature for a particular photocurable composition, the baking temperature that will be used during a post-exposure bake, a dose of actinic radiation that will be used to photocure the pre-cured layer 502, or a combination thereof. The temperature at the time of photocuring is referred to herein as the actual photocuring temperature. The actual photocuring temperature can be at or near the desired photocuring temperature. The actual photocuring temperature can be any of the targeted temperatures and tolerances previously described.

Referring to FIGS. 3, 10, and 11, the controller 350 or a local controller can receive a signal from a temperature sensor or a derivative of such signal and determine if the temperature is at or within a tolerance (for example, +/−5° C.+/−2° C., +/−1° C., or +/−0.5° C.) of the desired photocuring temperature. When the temperature is at or within a tolerance of the desired photocuring temperature, the controller 350 or a local controller can transmit a signal for an actinic radiation source 732 to be activated as illustrated in FIG. 11.

Actinic radiation is emitted from the actinic radiation source 732. At least 70% of the actinic radiation reaching the superstrate 422 is transmitted through the superstrate 422. The actinic radiation transmitted through the superstrate 422 activates the photoinitiator within photocurable composition in the pre-cured layer 502 to aid in polymerization of the polymerizable material within the photocurable composition. The actinic radiation can have a wavelength of at least 10 nm and less than 700 nm. The actinic radiation can be ultraviolet radiation having a wavelength in a range from 10 nm to 400 nm, and more particularly, in a range from 100 nm to 360 nm. A supplier of the photocurable composition may provide a targeted wavelength or a targeted range of wavelengths to be used to photocure the photocurable composition.

Energy from the exposure to actinic radiation forms a cured layer 702 (FIG. 11) from the pre-cured layer 502 (FIG. 10). The cured layer 702 has an upper surface 712. The energy substantially polymerizes the polymerizable material to form a polymer material. The polymer material can be a single polymer compound or may be a co-polymer. The exposure to the actinic radiation substantially polymerizes but may not fully polymerize the polymerizable material within the pre-cured layer 502. Further polymerization may occur during a post-exposure baking of the cured layer 702. A supplier of the photocurable composition may provide a targeted dose or a targeted range of doses to be used for the photocurable composition. Alternatively, skilled artisans may generate empirical data to determine a dose or range of doses that may be used for a particular photocurable composition.

The method can further include removing the superstrate 422 from the cured layer 702. The photocurable composition can include an internal mold release agent that remains in the cured layer 702 after polymerization. The internal mold release agent can help to reduce the likelihood of damaging the cured layer 702 or removing part or all of the cured layer 702 when removing the superstrate 422.

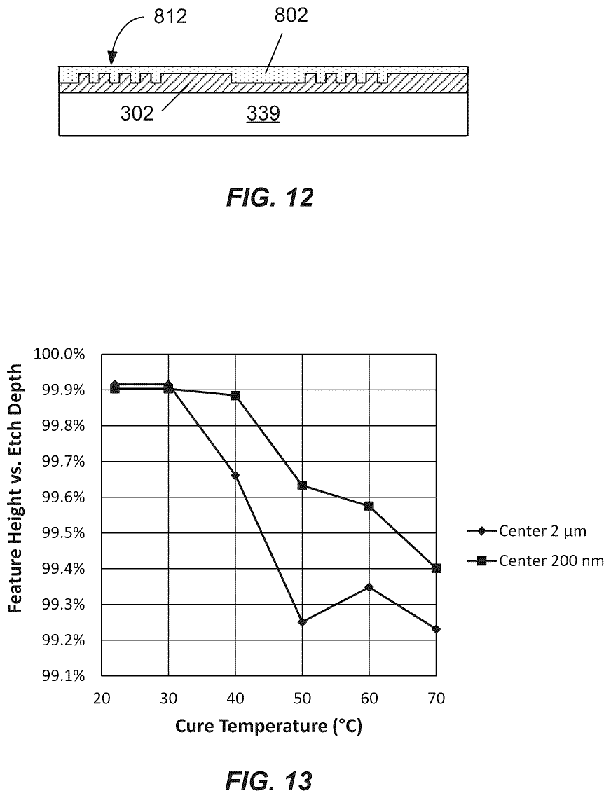

The method can include baking the cured layer to form a baked layer at block 229 in FIG. 6. During the baking operation, the material within the cured layer 702 can further polymerize, cross-link, or both. The baking operation can also help remove a relatively volatile component, if present, from the cured layer 702 when forming a baked layer 802 in FIG. 12. The baked layer 802 has an upper surface 812. The baking operation may or may not cause a further thickness change between the cured layer 702 and the baked layer 802.

Referring to FIGS. 3, 11, and 12, the controller 350 or a local controller can transmit a signal for the substrate transfer tool 310 to remove the substrate 302 and the cured layer 702 from the pre-exposure heat and photocure station 326 and move the substrate 302 and the cured layer 702 to the post-exposure bake station 329. The substrate transfer tool 310 can place the substrate 302 on the substrate chuck 339 within the post-exposure bake station 329.

A heating means within the post-exposure bake station 329 is used to heat the cured layer 702 (FIG. 11) to form the baked layer 802 (FIG. 12). Any of the heating means previously described with respect to the pre-exposure heat operation can be used for the baking operation. The heating means provides heat at a temperature higher than the temperature used for the pre-exposure heat operation. The baking temperature can be at least 100° C. higher than the photocuring temperature. The baking temperature can be at least 100° C., at least 150° C., or at least 200° C. The baking temperature should not be so high as to cause significant decomposition or another adverse effect to the baked layer 802. The baking temperature can be at most 500° C., at most 450° C., or at most 400° C. The baking temperature can be a value between any of the minimum and maximum numbers noted above, for example, in a range from 100° C. to 500° C., 150° C. to 450° C., or 200° C. to 400° C. In a particular implementation, the baking temperature can be in a range from 350° C. to 400° C.

A soak time is the time the substrate 302 and overlying polymer layer is at the baking temperature. The soak time needs to be sufficient to achieve a needed or desired amount of further polymerization, reduce the amount of a volatile component within the polymer layer to a desired amount, or both. The soak time can be at least 0.25 minute, at least 1 minute, or at least 3 minutes. After a long enough time, further exposure to the baking temperature may not sufficiently improve the polymer layer (a sufficient amount of polymerization has occurred, a remaining amount of the volatile component is low enough to not cause a problem during subsequent processing, etc.) or may start to cause an adverse effect, such as roughening the upper surface 812 of the baked layer 802, possible delamination of the baked layer 802 from the substrate 302, or the like. The soak time may be at most 60 minutes, at most 30 minutes, or at most 15 minutes. The soak time can be a value between any of the minimum and maximum numbers noted above, for example, in a range from 0.25 minute to 60 minutes, 1 minute to 30 minutes, or 3 minutes to 15 minutes.

The baking operation can be performed using a gas. The gas can include a material that is relatively inert to the cured layer 702 and the baked layer 802. The material can include N₂, CO₂, a noble gas (Ar, He, or the like), or a mixture thereof. The gas may not include an oxidizing material, for example O₂, O₃, N₂O, or the like, or may include no more than 10 mol % or no more than 0.5 mol % of the oxidizing material.

As illustrated, the post-exposure bake station 329 is configured to process a single substrate at a time. In another implementation, the post-exposure bake station 329 can be configured to process a plurality of substrates during the same baking operation. The post-exposure bake station 329 may include a cassette or another suitable substrate container or be capable of receiving the cassette or the other suitable substrate container, where the cassette or the other suitable substrate container can hold a plurality of substrates. The post-exposure bake station 329 may be within the apparatus 300 or may be outside of the apparatus 300.

Referring to FIG. 3, the controller 350 or a local controller can transmit a signal for the post-exposure bake station 329 to flow the inert gas within the post-exposure bake station 329 and control the heating means to maintain the substrate 302 and the cured layer 702 at a desired temperature for the soak time. After the soak time, the controller 350 or a local controller can transmit a signal for the substrate transfer tool 310 to remove the substrate 302 and baked layer 802 from the post-exposure bake station 329. The substrate 302 and baked layer 802 can be moved by the substrate transfer tool 310 to a chill plate to reduce the temperature of the substrate 302 and the baked layer 802 before the substrate 302 and baked layer 802 are moved back to the substrate pod 321. After chilling is completed, the controller 350 or a local controller can transmit signal for the substrate 302 and baked layer 802 to be moved to the substrate pod 321.

The methods have been described principally with respect to the apparatus 300 in FIG. 3. The methods for the apparatus 400 in FIG. 4 and the system 500, including the apparatuses 501 and 503, in FIG. 5 can be substantially the same except as described below.

Referring to FIG. 5, the post-exposure bake can be performed in the apparatus 503 that is different from the apparatus 501 that performs the dispense, pre-exposure heating, and photocuring. A human, a robot, a tram, or the like can transport a substrate pod with substrates and cured layers from the apparatus 501 to the apparatus 503, so that the cured layers can be baked to form baked layers.

The apparatus 400 in FIG. 4 allows significant operations in the method to be performed by a dedicated station. The pre-exposure heating is performed in the pre-exposure heat station 425, and the photocuring is performed in the photocure station 427, as compared to the pre-exposure heat and photocure station 326 where both pre-exposure heating and photocuring are performed. Each of the stations 425 and 427 can be optimized for their respective operations; however, processing may be more complicated. As a substrate with a heated pre-cured layer of the photocurable composition is transferred from the pre-exposure heat station 425 to the photocure station 427, some cooling of the heated pre-cured layer may occur before photocuring is performed. The targeted temperature during pre-exposure heating may be higher than the desired photocuring temperature to account for cooling during the transfer between the stations 425 and 427. As a non-limiting example, a desired photocuring temperature can be 60° C. The targeted temperature may be 63° C. to allow a 3° C. temperature drop between the end of pre-exposure heating and the photocuring of the heated pre-cured layer. Process control may be more difficult.

The apparatus 400 has a gantry-based dispense module 440. The gantry-based design may be useful if an apparatus has a plurality of dispense stations that share the dispense module 440. As another alternative, the dispense module 440 can be redesigned to fit within the dispense station 423. In another alternative, the dispense station 323 in FIG. 3 can replace the dispense station 423 and the dispense module 440 in FIG. 4.

The apparatus 400 can have stationary substrate chucks that may simplify the design of the apparatus 400 because a stage is not needed. Apparatus 300 (FIG. 3) and the apparatus 501 (FIG. 5) may be modified so that each station has a stationary substrate chuck.

However, with stationary substrate chucks, the substrate transfer tool 310 may transfer a substrate, a pre-cured layer, and a superstrate between different substrate chucks, and the position of the superstrate relative to the substrate may shift during the transfer. With stationary substrate chucks, the transfer operation using the substrate transfer tool 310 between stations may be slower to reduce the likelihood of the superstrate shifting relative to the substrate. In another implementation, any two or more of the substrate chucks 433, 435, and 437 in FIG. 4 can be replaced by the substrate chuck 333 in FIG. 3 that is coupled to a stage to allow movement of the substrate chuck 333 rather than moving the substrate between the substrate chucks 433, 435, and 437 in FIG. 4.

Further processing options are available for any one or more of the systems illustrated in FIGS. 3 to 5. In FIG. 10, the substrate 302, the pre-cure layer 502, and the superstrate 422 are heated together during the pre-exposure heating. The substrate 302, the photocurable composition (as droplets 322), or the superstrate 422 may be heated separately as part of the pre-exposure heating operation. The substrate 302 may be heated before or during the dispensing of droplets 322 of the photocurable composition, the photocurable composition may be heated before it is dispensed on the substrate 302, and the superstrate 422 may be heated before coming in contact with the droplets 322 of the photocurable composition. Separate heating may complicate the pre-exposure heating operation. For example, the substrate 302, with or without the droplets 322, and the superstate 422 can be separately heated before the superstate 422 contacts the droplets 322. The temperatures of the substrate 302 and the superstrate 422 may be different even if the temperatures were intended to be the same. One or both of the substrate 302, with or without the droplets 322, and the superstrate 422 may be heated to a targeted temperature that is higher than the desired photocuring temperature. After the pre-cured layer 502 is formed by contact with the superstrate 422, the combination of the substrate 302, the pre-cured layer 502, and the superstrate 422 can be allowed to cool down to a temperature at or near the desired photocuring temperature when the pre-cured layer 502 is photocured.

The superstrate 422 can be placed in contact with the droplets 322 when the substrate 302 and the droplets 322 are in the dispense station 323, the pre-exposure heat and photocure station 326 (FIGS. 3 and 5), or the pre-exposure heat station 425 or the photocure station 427 (FIG. 4). The superstrate 422 can have a size and shape similar to the substrate 302. The substrate transfer tool 310 can be used to place the superstrate 422 in contact with the droplets 322.

After reading this specification, skilled artisans will appreciate that many system configurations and processing options are available without deviating from the concepts described herein. Skilled artisans will be able to determine a particular system configuration and a particular method to use to meet the needs or desires for a particular application.

The process described above can be used in forming a planarization layer or a patterned resist layer from a photocurable composition. The process described above can be integrated as part of a manufacturing method of making an article. The article can be an electrical circuit element, an optical element, a microelectromechanical system (MEMS), a recording element, a sensor, a mold, an integrated circuit, or the like. The integrated circuit may be a solid state memory (such as a dynamic random access memory (DRAM), a static random access memory (SRAM), a flash memory, and a magnetoresistive memory (MRAM)), a microprocessor, a microcontroller, a graphics processing unit, a digital signal processor, a field programmable gate array (FPGA) or a semiconductor element, a power transistor, a charge coupled-device (CCD), an image sensor, or the like.

The method can further include an etching process to transfer an image into the substrate that corresponds to the pattern in one or both of the baked layer or patterned layers that are underneath the baked layer. The substrate can be further subjected to other processes for device (article) fabrication, including, for example, curing, oxidation, layer formation, deposition, doping, planarization, lithography, etching, formable material removal, dicing, bonding, and packaging, and the like. The substrate may be processed to produce a plurality of articles (devices), for example, the substrate may be a semiconductor wafer.

### EXAMPLES

Examples described below are provided to demonstrate that a thickness change of a layer formed from a photocurable composition can be affected by a temperature of the photocurable composition during photocuring. The examples are to aid in the understanding of the concepts described herein and not to limit the scope of the invention as defined in the appended claims. In the Examples, values for thickness changes are rounded off to the nearest tenth of a percent.

Table 4 below includes photocurable compositions A, B, C, and D used for the examples. The values in the table are parts by weight for each of the components within the photocurable compositions.

TABLE 4
Photocurable Compositions Used in the Examples

Photocurable Composition

| Component | A | B | C | D |
|---|---|---|---|---|
| TMPTA | 35 | | | |
| mXDA | 65 | | | |
| VmXDA | | 30 | | |
| DVBA | | 45 | | |
| DVBPH | | | 100 | |
| 3VBPH | | 25 | | |
| TVPM | | | | 100 |
| Irgacure 819 | 2 | 3 | 3 | 3 |
| Irgacure OXE-02 | | 3 | 3 | 3 |
| FS2000M1 | 0.5 | | | |
| FS-3100 | | 1 | 0.5 | 1 |

1. Thickness Change Caused by Photocuring Unaffected by Geometry of Features within Substrate

Example 1 demonstrates the thickness change caused by photocuring is not significantly affected by different line/space dimensions. For all samples in Example 1, the photocurable composition D was deposited on substrates. The photocurable composition D for some of the substrates was patterned using a template having an area with a pattern of 200 nm lines and 200 nm spaces and another area with a pattern of 2 μm lines and 2 μm spaces. The etch depths (50 nm) of the template in these two areas were measured, so the initial height of the features made from the photocurable composition D is known prior to photocuring. For all samples in Example 1, the photocurable composition D was exposed to actinic radiation at a dose of 15 J/cm² during photocuring. Data were collected for photocuring temperatures of 22° C. to 70° C. The thickness change is determined by Equation 3 above, where T₁ is the etch depth of the template, and T₂ is the thickness of the corresponding cured layer. FIG. 13 includes the data and compares the thickness change for the different patterns. The Y-axis is the thickness change between the cured layer (after exposure to actinic radiation and before the post-exposure bake) and the layer of the initially patterned layer of photocurable composition.

For the line corresponding to the pattern having 200 nm lines and 200 nm spaces (“Center 200 nm”), the thickness change for the layer is approximately −0.1% when the temperature of the photocurable composition at exposure is in a range from 22° C. to 40° C. As the temperature of the photocurable composition D during photocuring increases from 40° C. to 70° C., the thickness change for the layer increases from −0.1% to −0.6%.

For the line corresponding to the pattern having the 2 μm lines and 2 μm spaces (“Center 2 μm”), the thickness change for the layer is approximately-0.1% when the temperature of the photocurable composition at exposure is in a range from 22° C. to 30° C. As the temperature of the photocurable composition D during photocuring increases from 30° C. to 70° C., the thickness change for the layer increases from −0.1% to −0.8%.

FIG. 13 shows the same general trend for both patterns. For the same photocuring temperature, the thickness changes were not significantly affected by different patterns used to form lines and spaces from the photocurable composition. Thus, the thickness change, when expressed as a percentage, is not significantly dependent on the underlying geometry of the substrate.

### 2. Thickness Change Caused by Post-Exposure Baking

Example 2 demonstrates the thickness change between a cured layer and its corresponding baked layer, and thus, the thickness change corresponds to the baking operation and not the photocuring operation. The thickness change is determined by Equation 3 above, where T₁ is the thickness of the cured layer, and T₂ is the thickness of the corresponding baked layer. For all samples in Example 2, the photocurable composition D was exposed to actinic radiation at a dose of 15 J/cm² during photocuring. Data were collected for photocuring temperatures of 22° C. to 70° C. One subset of the data was generated at a baking temperature of 350° C. and a soak time of 2 minutes, and another subset of data was generated at a baking temperature of 400° C. and a soak time of 2 minutes. Baking was performed at an N₂ ambient temperature. For each substrate, the thicknesses of the cured layer and the baked layer were measured at an array of locations across the substrate.

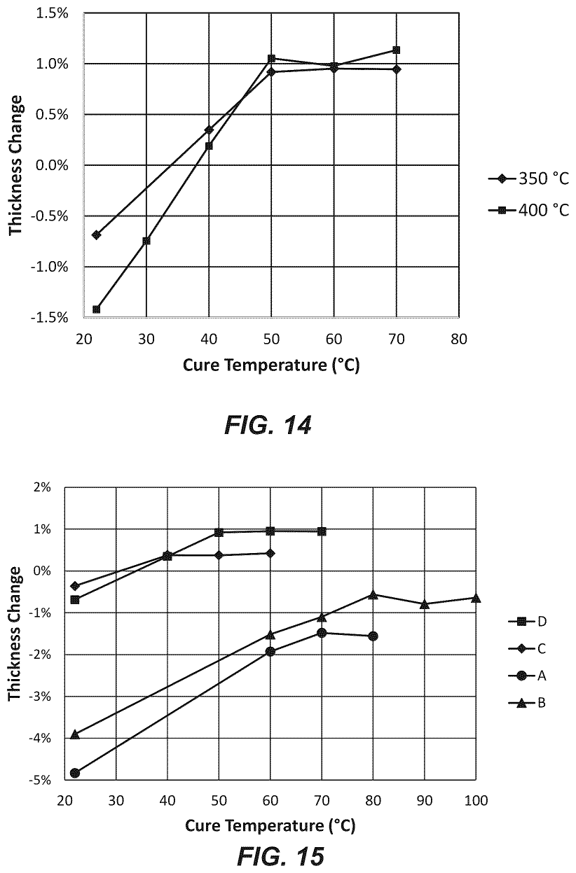

FIG. 14 includes the data and compares the different baking temperatures. The data for both baking temperatures have linear increases in thickness change as the photocuring temperature increases from 22° C. to 50° C. For the 350° C. bake, the thickness change is-0.7% at a photocuring temperature of 22° C., and the thickness change is 0.9% at a photocuring temperature of 50° C. For the 400° C. bake, the thickness change is-1.4% at a photocuring temperature of 22° C., and the thickness change is 1.1% at a photocuring temperature of 50° C. For both baking temperatures, the thickness change is substantially constant at approximately 1.0% for photocuring temperatures in a range from 50° C. to 70° C. For the 350° C. bake, the thickness change is approximately 0.0% at a photocuring temperature of approximately 33° C. For the 400° C. bake, the thickness change is approximately 0.0% at a photocuring temperature of approximately 38° C.

The Y-axis in FIG. 14 has a range of 3.0% (from −1.5% to 1.5%), which is approximately 3.3 times greater than the range of the Y-axis in FIG. 13, which has a range of 0.9% (from 99.1% to 100.0%). Thus, for the photocurable composition D, the thickness change that occurs during the bake is substantially greater than the thickness change that occurs during the photocuring.

### 3. Thickness Change Between the Cured Layer and the Corresponding Baked Layer for Different Photocurable Compositions

Example 3 demonstrates the thickness change between a cured layer and its corresponding baked layer for the photocurable compositions A, B, C, and D. The thickness change is determined by Equation 3 above, where T₁ is the thickness of the layer of the cured layer, and T₂ is the thickness of the corresponding baked layer. The photocurable composition A was dispensed over substrates and planarized using a superstrate that is a flat blank. The photocurable composition A was photocured by exposing the photocurable composition A to actinic radiation at a dose of 1.2 J/cm² to form cured layers. The photocurable composition B was dispensed over substrates and planarized using a flat blank. The photocurable composition B was photocured by exposing the photocurable composition B to actinic radiation at a dose of 20 J/cm² to form cured layers. The photocurable composition C was dispensed over substrates and planarized using a flat blank. The photocurable composition C was photocured by exposing the photocurable composition C to actinic radiation at a dose of 5 J/cm² to form cured layers. The photocurable composition D was dispensed over substrates and planarized using a flat blank. The photocurable composition D was photocured by exposing the photocurable composition D to actinic radiation at a dose of 15 J/cm² to form cured layers. After photocuring, the substrates and cured layers were baked in an N₂ ambient at a temperature of 350° C. for a soak time of 2 minutes to form baked layers over the substrates. Thickness change measurements were based on film thicknesses measured before and after baking.

FIG. 15 includes a graph of the thickness change as a function of the photocuring temperature for the four photocurable compositions. Each of the slopes of the lines include a linear portion with a positive slope and a flat portion, where the thickness change is substantially constant (thickness changes are no more than the absolute value of 0.2%) with a further increase in photocuring temperature. A transition temperature is the photocuring temperature where the linear portion of a line and the flat portion of the line meet. Thus, the transition temperature marks a point where a further increase in the photocuring temperature will not significantly affect the thickness change.

For the photocurable composition A, the linear portion extends from 22° C. having a thickness change of −4.8% to the transition temperature of 70° C. having a thickness change of −1.5%. The flat portion of the line starts at the transition temperature of 70° C. The thickness change at a photocuring temperature of 80° C. is −1.6%.

For the photocurable composition B, the linear portion extends from 22° C. having a thickness change of −3.9% to the transition temperature of 80° C. having a thickness change of −0.6%. The flat portion of the line starts at the transition temperature of 80° C. The thickness change at a photocuring temperature of 90° C. is −0.8%, and the thickness change at a photocuring temperature of 100° C. is −0.6%.

For the photocurable composition C, the linear portion extends from 22° C. having a thickness change of −0.4% to the transition temperature of 40° C. having a thickness change of 0.4%. The flat portion of the line starts at the transition temperature of 40° C. The thickness change at a photocuring temperature of 50° C. is 0.4%, and the thickness change at a photocuring temperature of 60° C. is 0.4%.

For the photocurable composition D, the linear portion extends from 22° C. having a thickness change of −0.7% to the transition temperature of 50° C. having a thickness change of 0.9%. The flat portion of the line starts at the transition temperature of 50° C. The thickness change at a photocuring temperature of 60° C. is 1.0%, and the thickness change at a photocuring temperature of 70° C. is 0.9%.

The photocurable compositions C and D can be processed and result in a thickness change of 0% between the thickness of the baked layer and the cured layer. For the photocurable composition C, a thickness change of 0% can be obtained at a photocuring temperature of 31° C. and for the photocurable composition D, a thickness change of 0% can be obtained at a photocuring temperature of 35° C.

### 4. Thickness Changes for Different Photocuring Temperatures as a Function of Dose of Actinic Radiation

Example 4 demonstrates the thickness change between cured layers and the corresponding baked layer when the photocurable composition was photocured at different photocuring temperatures. The thickness change is determined by Equation 3 above, where T₁ is the thickness of the cured layer, and T₂ is the thickness of the corresponding baked layer.

In Example 4, the photocurable composition B was photocured at photocuring temperatures of 22° C., 60° C., and 80° C., and the corresponding cured layers were baked in N₂ ambient at 350° C. for a soak time of 2 minutes.

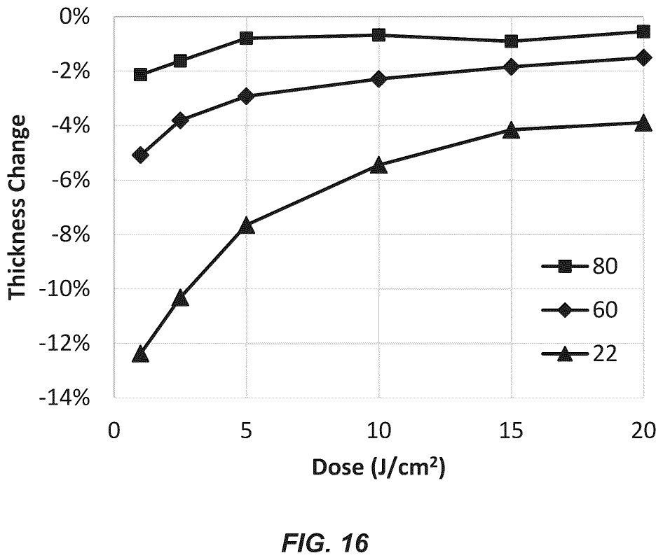

FIG. 16 includes a data for the samples. For the same photocuring temperature, each of the lines has an asymptotic rise in the thickness change as a function of dose. The thickness change becomes closer to a 0% thickness change as the dose is increased from 1 J/cm² to 20 J/cm². Significantly lower doses can be used when photocuring at relatively higher temperatures. The thickness change is −3.8% at a dose of 2.5 J/cm² and a photocuring temperature of 60° C., and the thickness change is-3.9% at a dose of 20 J/cm² and a photocuring temperature of 22° C. The thickness change is-1.6% at a dose of 2.5 J/cm² and a photocuring temperature of 80° C., and the thickness change is-1.9% at a dose of 15 J/cm² and a photocuring temperature of 60° C. Thus, a relatively lower dose can be used at a relatively higher photocuring temperature to achieve the same or better thickness change (closer to 0%). The data in Example 4 suggest using a relatively higher temperature so that a lower dose may be used.

Some photocurable compositions can use a moderate photocuring temperature (such as in a range from 30° C. to 50° C.) and achieve a 0% thickness change. Referring to Example 3 and FIG. 15, the photocurable compositions C and D can achieve a 0% thickness change at photocuring temperatures of 31° C. and 35° C., respectively. Thus, too high of a photocuring temperature for the photocurable composition C or D may result in a thickness change that is further from 0% as compared to the transition temperatures.

Alternatively, the dose of actinic radiation may be reduced, which would shift the lines, including the lines for the photocurable compositions C and D, in FIG. 15 downward. Empirical data can be generated when the photocuring temperatures are at the transition temperatures (transition between the linear portions and flat portions of the lines), 40° C. for the photocurable composition C and 50° C. for the photocurable composition D, to determine a dose that produces a 0% thickness change. For the photocurable compositions C and D, a temperature higher than the transition temperature would not significantly improve throughput because further lowering the dose would result in a thickness change farther from 0%. Thus, photocuring temperatures of 50° C. and greater would waste energy and not significantly improve the likelihood of achieving a 0% thickness change.

Embodiments as described herein can be used to keep a thickness change between a baked layer and a pre-cured layer or between a baked layer and a cured layer of a photocurable composition closer to 0% when comparing photocuring temperature at higher than ambient temperature as compared to photocuring at ambient temperature. A moderate photocuring temperature, as compared to too low or too high of a photocuring temperature, may allow a thickness change of 0% to be achieved. Better dimensional stability helps to make processes more robust and repeatable from substrate to substrate and from production lot to production lot. The inventors have found that for each material there is photocure thickness change that is dependent upon the photocuring temperature and there is baking thickness change that is dependent upon the baking temperature. The inventors have found that it is possible to select that one of the photocure thickness change and baking thickness change is positive while the other is negative so as to give an optimal thickness change as close to zero as possible.

Note that not all of the activities described above in the general description or the examples are required, that a portion of a specific activity may not be required, and that one or more further activities can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A system, comprising:
a first heating means for heating a photocurable composition over a substrate;
an actinic radiation source configured to emit actinic radiation at a wavelength less than 700 nm; and
a controller configured to determine a targeted temperature to be produced by the first heating means to achieve a photocuring temperature of the photocurable composition when the photocurable composition is exposed by the actinic radiation source, wherein the photocuring temperature is greater than an ambient temperature.

2. The system of claim 1, wherein the system includes an apparatus, and the first heating means and the actinic radiation source are within a same station within the apparatus.

3. The system of claim 1, further comprising:
a first substrate chuck configured to hold the substrate when the photocurable composition is at the photocuring temperature and exposed to the actinic radiation.

4. The system of claim 3, further comprising:
a second substrate chuck configured to hold the substrate when the photocurable composition is exposed to the first heating means; and
a substrate transfer tool configured to transfer the substrate having the photocurable composition between the first substrate chuck and the second substrate chuck.

5. The system of claim 1, further comprising:
a dispense head configured to dispense the photocurable composition over the substrate.

6. The system of claim 1, further comprising:
a station configured to place a superstrate in contact with the photocurable composition overlying the substrate.

7. The system of claim 1, further comprising:
a second heating means configured to heat a cured layer corresponding to the photocurable composition to form a baked layer, wherein the second heating means is configured to heat the substrate and the cured layer to a baking temperature higher than the photocuring temperature.

8. The system of claim 1, further comprising:
a temperature sensor configured to generate a first signal corresponding to a temperature of the photocurable composition,
wherein the controller is further configured to receive the first signal and to transmit a second signal for the actinic radiation source to be activated when the temperature is at the photocuring temperature+/−5° C.

9. A method, comprising:
dispensing a photocurable composition over a substrate, wherein the photocurable composition comprises a multifunctional monomer;
photocuring the photocurable composition while the photocurable composition is at a photocuring temperature higher than an ambient temperature, wherein photocuring the photocurable composition forms a cured layer over the substrate; and
baking the cured layer to form a baked layer, wherein baking is performed at a baking temperature higher than the photocuring temperature.

10. The method of claim 9, wherein the photocuring temperature is greater than 25° C.

11. The method of claim 10, wherein the baking temperature is at most 500° C.

12. The method of claim 9, wherein the photocurable composition is at the photocuring temperature while the photocurable composition is in contact with the substrate and a superstrate.

13. The method of claim 9, wherein:
a cured thickness is a thickness of the cured layer of the photocurable composition before baking,
a baked thickness is a thickness of the baked layer,
a thickness change is:
((T₂−T₁)/T₁)*100%, where
T₁ is the cured thickness, and
T₂ is the baked thickness, and
the thickness change is in a range from −2.0% to 2.0%.

14. The method of claim 9, wherein the multifunctional monomer comprises a difunctional monomer, a trifunctional monomer, or a tetrafunctional monomer.

15. The method of claim 9, wherein the multifunctional monomer includes two or more vinyl groups.

16. The method of claim 15, wherein the multifunctional monomer includes at least one aromatic ring structure.

17. The method of claim 9, wherein the multifunctional monomer comprises an acrylate group.

18. The method of claim 9, wherein the photocurable composition has a multifunctional monomer content of at least 90% by weight of the photocurable composition.

19. The method of claim 9, further comprising:
receiving the baking temperature at which the cured layer is to be baked; and
determining the photocuring temperature based on the baking temperature.

20. A system, comprising:
a photocure station configured to form a cured layer over a substrate at a photocuring temperature, wherein the photocuring temperature is higher than an ambient temperature;
a bake station configured to bake the cured layer at a baking temperature to form a baked layer; and
a controller configured to determine the photocuring temperature based at least in part on the baking temperature.

21. The system of claim 20, wherein the photocure station comprises:
a heating means configured to heat a photocurable composition over the substrate to a temperature at or closer to the photocuring temperature than the ambient temperature; and
an actinic radiation source configured to emit radiation at a wavelength less than 700 nm.

22. The system of claim 20, further comprising:
a robot arm configured to move the substrate with the cured layer from the photocure station to the bake station.
